(19) United States
(12) Patent Application Publication
(10) Pub. No.: US 2005/0005854 A1
(43) Pub. Date: Jan. 13, 2005

(54) Surface wave plasma treatment apparatus using multi-slot antenna

(75) Inventor: Nobumasa Suzuki, Ibaraki (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 10/870,067

(22) Filed: Jun. 18, 2004

(30) Foreign Application Priority Data
Jul. 8, 2003 (JP) 2003-271876

(51) Int. Cl. C23C 16/00

(52) U.S. Cl. 118/723 MW

(57) ABSTRACT

A surface wave plasma treatment apparatus according to the present invention is a surface wave plasma treatment apparatus composed of a plasma treatment chamber including a part where the chamber is formed as a dielectric window capable of transmitting a microwave, a supporting body of a substrate to be treated, the supporting body set in the plasma treatment chamber, a plasma treatment gas introducing unit for introducing a plasma treatment gas into the plasma treatment chamber, an exhaust unit for evacuating an inside of the plasma treatment chamber, and a microwave introducing unit using a multi-slot antenna arranged on an outside of the dielectric window to be opposed to the supporting unit of the substrate to be treated, wherein slots arranged radially and slots arranged annularly are combined as slots.

### BACKGROUND OF THE INVENTION

1. Field of the Invention

The present invention relates to a microwave plasma treatment apparatus. The present invention more particularly relates to a microwave plasma treatment apparatus capable of adjusting a plasma distribution in a radial direction especially.

2. Description of Related Art

As a plasma treatment apparatus using a microwave as an excitation source for plasma generation, a chemical vapor deposition (CVD) apparatus, an etching apparatus, an ashing apparatus and the like are known.

Because the microwave plasma treatment apparatus uses a microwave as the excitation source of a gas, the microwave plasma treatment apparatus can accelerate electrons by an electric field having a high frequency, and thereby can effectively ionize and excite gas molecules. Consequently, the microwave plasma treatment apparatus has advantages that the ionization efficiency, the excitation efficiency and the resolution efficiency of a gas are high to be able to form a high density plasma comparatively easily, and that a high quality treatment can be done at a low temperature and at a high speed. Moreover, because the microwave has a property of being transmitted by a dielectric material, a plasma treatment apparatus can be configured to be an electrodeless discharge type one. Consequently, the microwave plasma treatment apparatus has also an advantage that a highly clean plasma treatment can be performed.

For further increasing the speed of such a microwave plasma treatment apparatus, a plasma treatment apparatus using electron cyclotron resonance (ECR) has been put to practical use. The ECR is a phenomenon of the generation of high density plasma by electrons which resonantly absorb a microwave to be accelerated when the electron cyclotron frequency, which is the frequency of the electrons revolving around lines of magnetic force, coincides with the general frequency 2.45 GHz of the microwave at the time of the magnetic flux density of 87.5 mT. In such an ECR plasma treatment apparatus, the following four representative configurations of microwave introducing means and magnetic field generation means are known.

That is, they are (1) a configuration in which a microwave propagating through a wave guide is introduced into a cylindrical plasma generation chamber through a transmission window from an opposed surface of a substrate to be treated and a diverging magnetic field having the same axis as the central axis of the plasma generation chamber is introduced through magnet coils provided on the periphery of the plasma generation chamber (NTT system), (2) a configuration in which a microwave being transmitted through a wave guide is introduced into a plasma generation chamber in the shape of a hanging bell from an opposed surface of a substrate to be treated and a magnetic field having the same axis as the central axis of the plasma generation chamber is introduced through magnet coils provided on the periphery of the plasma generation chamber (Hitachi system), (3) a configuration in which a microwave is introduced into a plasma generation chamber from a periphery through a Lisitano coil, or a kind of a cylindrical slot antenna, and a magnetic field having the same axis as the central axis of the plasma generation chamber is introduced by means of magnet coils provided on the periphery of the plasma generation chamber (Lisitano system), and (4) a configuration in which a microwave being transmitted through a wave guide is introduced into a cylindrical plasma generation chamber through a planer slot antenna from an opposed surface of a substrate to be treated and a loop magnetic field parallel to an antenna plane is introduced by means of permanent magnets provided on the back face of the planer antenna (planer slot antenna system).

As an example of a microwave plasma treatment apparatus, recently, an apparatus using an endless ring-shaped waveguide composed of a plurality of slots formed on an H-surface as a uniform and efficient introducing apparatus of a microwave has been proposed (U.S. Pat. No. 5,487,875, U.S. Pat. No. 5,538,699 and U.S. Pat. No. 6,497,783). The microwave plasma treatment apparatus is shown in FIG. 4A, and the plasma generation mechanism thereof is shown in FIG. 4B. A reference numeral 501 denotes a plasma treatment chamber; a reference numeral 502 denotes a substrate to be treated; a reference numeral 503 denotes a supporting body of the substrate to be treated 502; a reference numeral 504 denotes substrate temperature adjusting means; a reference numeral 505 denotes plasma treatment gas introducing means provided on the periphery of the plasma treatment chamber 501; a reference numeral 506 denotes an exhaust gas; a reference numeral 507 denotes a planer dielectric window for separating the plasma treatment chamber 501 from the atmosphere side; a reference numeral 508 denotes an endless ring-shaped waveguide with slots for introducing a microwave into the plasma treatment chamber 501 through the planer dielectric window 507; a reference numeral 511 denotes an E-branch of a feed port for introducing a microwave into the endless ring-shaped waveguide with slots 508; a reference numeral 512 denotes standing waves generated in the endless ring-shaped waveguide with slots 508; a reference numeral 513 denotes slots; a reference numeral 514 denotes surface waves propagating on the surface of the planer dielectric window 507; a reference numeral 515 denotes surface standing waves generated by the mutual interference of the surface waves 514 from the adjacent slots 513; a reference numeral 516 denotes generation section plasma generated by the surface standing waves 515; a reference numeral 517 denotes a plasma bulk generated by the diffusion of the generation section plasma 516.

By the use of the microwave plasma treatment apparatus as described above, it is possible to generate high density low electron temperature plasma having an electron density equal to 10¹² cm⁻³ or more, an electron temperature equal to 2 eV or less and plasma potential equal to 10 V or less, which plasma is formed in a large aperture space having a diameter of about 300 mm in a uniformity within ±3% by a microwave having the power of 1 kW or more. Consequently, gas can be fully reacted to be supplied to the substrate in an active state, and the damage of the surface of the substrate owing to incident ions is also reduced. Hence, the treatment of high quality, uniform and of a high speed can be implemented even at a low temperature.

However, when the microwave plasma treatment apparatus described above is used, the surface wave propagates on the surface of the dielectric window in the direction perpendicular to the slots, i.e. the peripheral direction. Consequently, there can occur the case where the electric field strength of the surface wave becomes weak at positions on the inside from the position of the slots to decrease the process speed of the plasma at the central part.

### SUMMARY OF THE INVENTION

The present invention relates to a plasma treatment apparatus which strengthens surface wave electric field strength on the inside and adjusts the distribution in a radial direction and further improves uniformity especially.

A surface wave plasma treatment apparatus according to the present invention is a surface wave plasma treatment apparatus composed of a plasma treatment chamber including a part where the chamber is formed as a dielectric window capable of transmitting a microwave; a supporting body of a substrate to be treated, the supporting body set in the plasma treatment chamber; plasma treatment gas introducing means for introducing a plasma treatment gas into the plasma treatment chamber; exhaust means for evacuating an inside of the plasma treatment chamber; and microwave introducing means using a multi-slot antenna arranged on an outside of the dielectric window to be opposed to the supporting means of the substrate to be treated, wherein slots arranged radially along which surface waves propagate into peripheral directions and slots arranged annularly along which the surface waves propagate into radial directions are combined as slots.

Moreover, the microwave introducing means may be a multi-slot antenna including an endless ring-shaped waveguide having an H surface on which the slots are formed.

Moreover, each interval of centers of the slots arranged radially may be odd times as long as a half wavelength of a surface wave.

Moreover, a diameter of a circle formed by connecting arcs of the slots arranged annularly with each other may be even times as long as a half wavelength of a surface wave.

Moreover, a plasma distribution in a radial direction may be adjusted by changing microwave emissivities of both of the slots arranged radially and the slots arranged annularly relatively.

Moreover, the adjustment of the plasma distribution may be performed by changing lengths of the slots arranged radially and central angles of the slots arranged annularly.

Moreover, the adjustment of the plasma distribution may be performed by changing widths of the slots arranged radially and the slots arranged annularly.

Moreover, the adjustment of the plasma distribution may be performed by changing thicknesses of the slots arranged radially and the slots arranged annularly.

Consequently, in the surface wave plasma treatment apparatus according to the present invention, because the slots arranged radially and the slots arranged annularly are combined, it is possible to provide the plasma treatment apparatus which strengthens surface wave electric field strength on the inside and adjusts the distribution in a radial direction and further improves uniformity especially.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIGS. 1A and 1B are schematic diagrams of a microwave plasma treatment apparatus of an embodiment of the present invention;

FIGS. 2A, 2B and 2C are views showing surface wave electric field strength distributions obtained by electromagnetic wave simulations for illustrating the present invention;

FIGS. 3A and 3B are views showing plasma density distributions obtained by probe measurements for illustrating the present invention; and

FIGS. 4A and 4B are schematic views of a conventional microwave plasma treatment apparatus.

### DETAILED DESCRIPTION OF THE PREFERRED EMBODIMENTS

Preferred embodiments of the present invention will now be described in detail in accordance with the accompanying drawings.

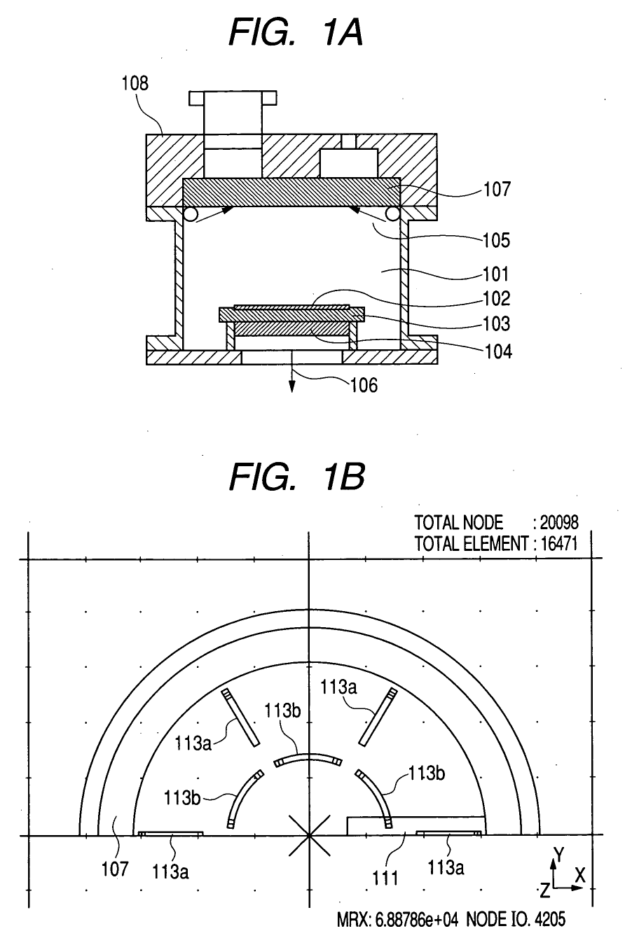

A microwave plasma treatment apparatus of an embodiment of the present invention will be described by means of FIGS. 1A and 1B. A reference numeral 101 denotes a plasma treatment chamber; a reference numeral 102 denotes a substrate to be treated; a reference numeral 103 denotes a supporting body of the substrate to be treated 102; a reference numeral 104 denotes substrate temperature adjusting means; a reference numeral 105 denotes plasma treatment gas introducing means provided on the periphery of the plasma treatment chamber 101; a reference numeral 106 denotes an exhaust gas; a reference numeral 107 denotes a dielectric window for separating the plasma treatment chamber 101 from the atmosphere side; a reference numeral 108 denotes an endless ring-shaped waveguide with slots for introducing a microwave into the plasma treatment chamber 101 through the dielectric window 107; a reference numeral 111 denotes an E-branch for distributing a microwave into right and left sides; a reference numeral 113a denotes slots arranged radially; a reference numeral 113b denotes slots arranged annularly.

Plasma treatment is performed as follows. The inside of the plasma treatment chamber 101 is evacuated through an exhaust system (not shown). Successively, a treatment gas is introduced into the plasma treatment chamber 101 at a predetermined flow rate through the gas introducing means 105 provide on the periphery of the plasma treatment chamber 101. Next, a conductance valve (not shown) provided in the exhaust system (not shown) is adjusted to keep the inside of the plasma treatment chamber 101 at a predetermined pressure. Desired electric power is supplied to the inside of the plasma treatment chamber 101 from a microwave power source (not shown) through the endless ring-shaped waveguide 108, the slots arranged radially 113a and the slots arranged annularly 113b. At this time, the microwave introduced in the endless ring-shaped waveguide 108 is distributed into two parts on the right side and the left side at the E-branch 111, and propagates at a guide wavelength longer than that in a free space. Both of the distributed microwaves interfere with each other to generate a standing wave having an “antinode” at every half guide wavelength. The microwave is transmitted by the dielectric window 107 through the slots arranged radially 113a and the slots arranged annularly 113b, which are provided to across surface currents, to be introduced into the plasma treatment chamber 101. Initial high density plasma is generated in the vicinity of the slots arranged radially 113a and the slots arranged annularly 113b by the microwave introduced into the plasma chamber 101. In this state, the microwave entered the interface between the dielectric window 107 and the initial high density plasma cannot propagate in the initial high density plasma, but propagates along the interface between the dielectric window 107 and the initial high density plasma as a surface wave. The surface waves introduced from one of the slots arranged radially 113a and one of the slots arranged annularly 113b which are adjacent to each other interfere with each other to generate a surface standing wave having an “antinode” at every half wavelength of the surface waves. Surface plasma is generated by the surface standing wave. Moreover, the diffusion of the surface plasma generates bulk plasma. The treatment gas is excited by the generated surface wave interference plasma to treat the surface of the substrate to be treated 102 placed on the supporting body 103.

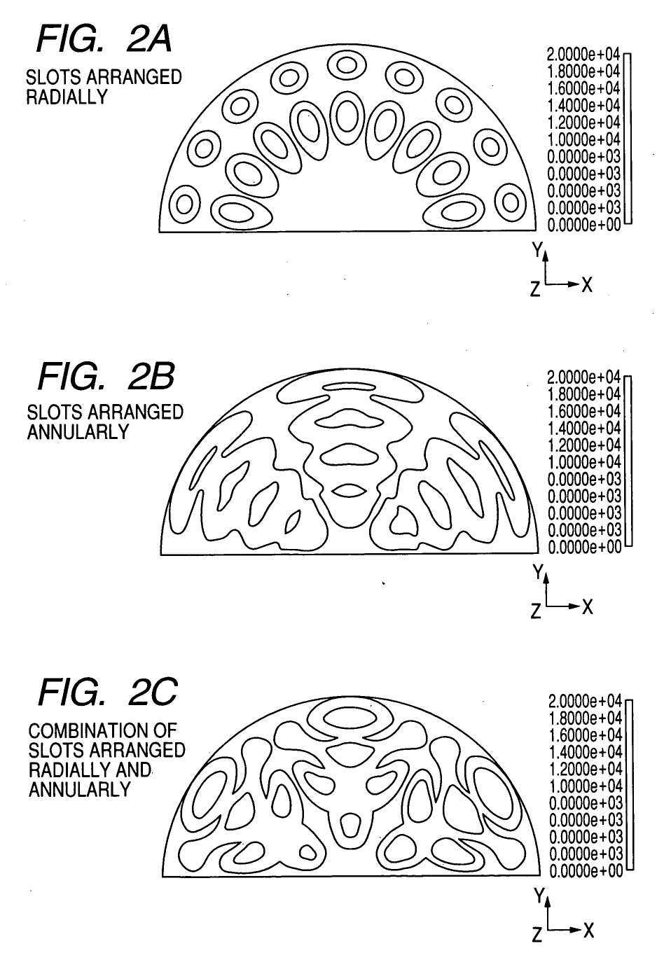

FIGS. 2A, 2B and 2C show surface wave electric field strength distributions obtained by electromagnetic wave simulation in the case where only the slots arranged radially 113a are used, in the case where only the slots arranged annularly 113b are used, and in the case where both of the slots arranged radially 113a and the slots arranged annularly 113b are combined, respectively. In the case where only the slots arranged radially 113a are used, surface waves propagate in the peripheral directions, and surface standing waves distribute on the side near to the outside, and the surface wave strength at the central part is weak. However, when the slot arranged annularly 113b, by which the surface waves propagate in radial directions and which can generate surface standing waves also at the central part, is combined, the surface wave electric filed can be distributed on almost the whole surface.

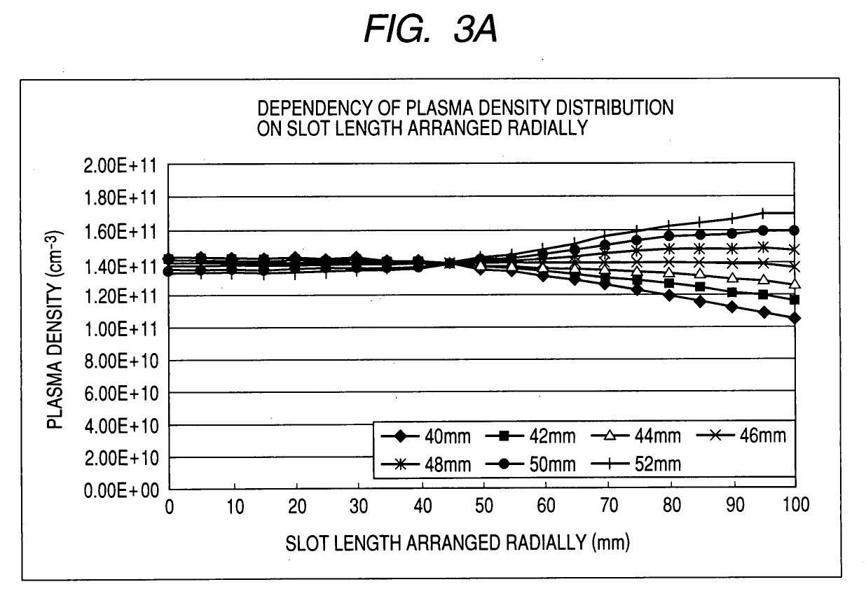

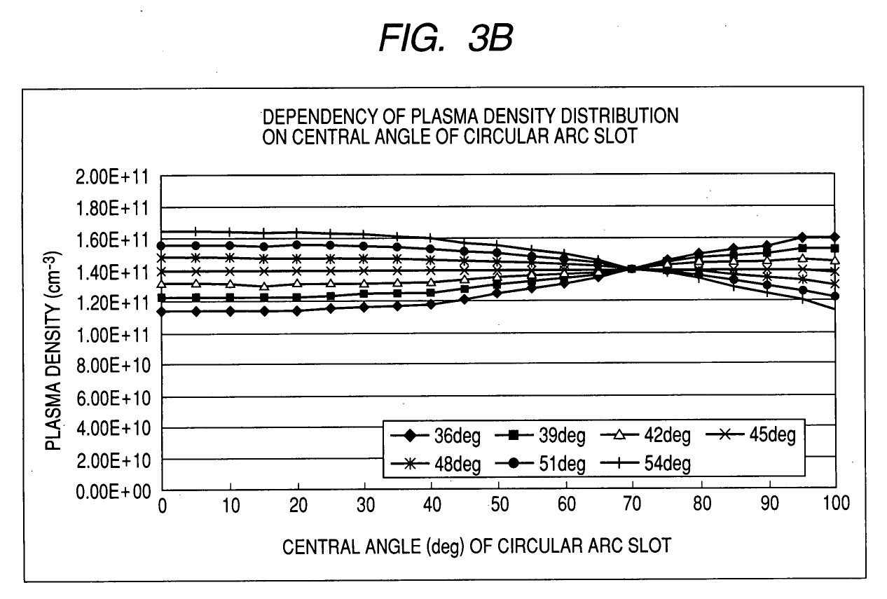

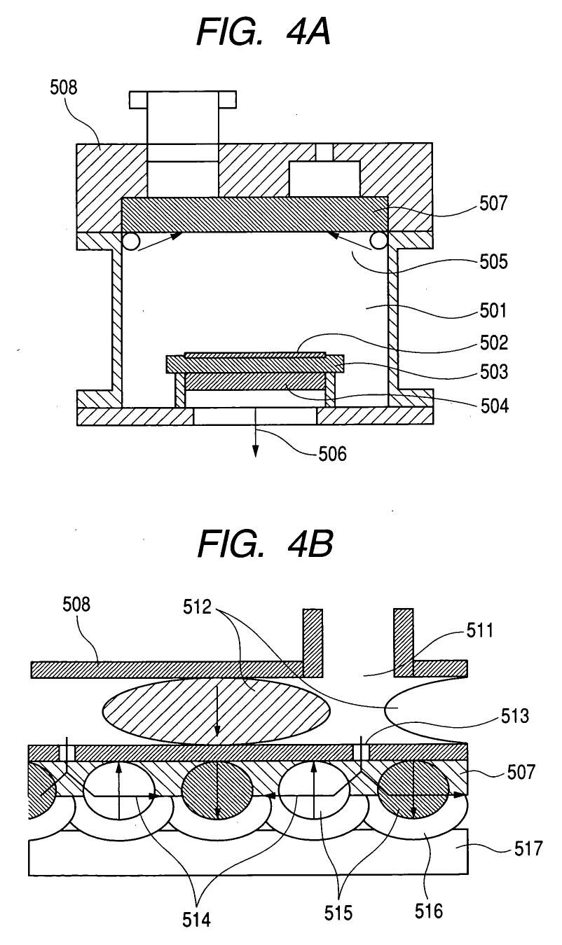

FIGS. 3A and 3B show plasma density distributions in the case where the lengths of the slots arranged radially 113a and the central angles of the slots arranged annularly are changed, respectively. When the slots arranged radially 113a are sufficiently short, upward convex distributions approximate to those in case of using only the slots arranged annularly 113b are shown. On the other hand, when the central angles of the slots arranged annularly 113b are sufficiently small, downward convex distributions approximate to those in case of using only the slots arranged radially 113a are shown. As the lengths of the slots arranged radially 113a increase, the plasma density on the outer side increases, and the plasma density distributions changes from the upward convex shapes to the flat shapes, and further to somewhat downward convex shapes. On the other hand, as the central angles of the slots arranged annularly 113b increase, the plasma density on the inner side increases, and the plasma density distributions changes from the downward convex shapes to the flat shapes, and further to somewhat upward convex shapes.

In such a way, by changing the lengths of the slots arranged radially 113a and the central angles of the slots arranged annularly 113b, the plasma density distributions in radial directions can be adjusted, and it is possible to obtain uniform distributions. It is also realized by changing introducing rates by changing the widths or the thicknesses in addition to changing the lengths.

The slots arranged radially to be used for the microwave plasma treatment apparatus of the present invention, the number of which slots is (waveguide—peripheral length/guide half-wavelength), are formed at the positions of the nodes of a standing wave in the ring-shaped waveguide at equiangular intervals in the range of the lengths within from ⅛ to ½ of the guide wavelength, more minutely in the range of from 3/16 to ⅜.

The slots arranged annularly to be used for the microwave plasma treatment apparatus of the present invention, the number of which slots is (waveguide—peripheral length/guide half-wavelength), are formed at the positions of the antinodes of the standing wave in the ring-shaped waveguide at equal intervals in the range of the central angles within from 360°×(guide half-wavelength)/waveguide—½×peripheral length to 360°×(guide half-wavelength)/waveguide—9/10×peripheral length, more minutely in the range of from 360°×(guide half-wavelength)/waveguide—⅗×peripheral length to 360°×(guide half-wavelength)/waveguide—⅘×peripheral length.

The frequency within a range of from 300 MHz to 3 THz can be applied as that of the microwave to be used for the microwave plasma treatment apparatus of the present invention, and the frequency within a range of from 1 GHz to 10 GHz, in which range the wavelength is at the same level as the size of the dielectric window 107, is especially effective.

Any materials having sufficient mechanical strength and having small dielectric defects in order that the transmission factor of the microwave may be sufficiently high can be applied to the material of the dielectric window 107 to be used for the microwave plasma treatment apparatus of the present invention. For example, quartz, alumina (sapphire), aluminum nitride, carbon-fluorine polymer (Teflon) and the like are optimum.

Any conductive materials can be used as the material of the endless ring-shaped waveguide with slots 108 to be used for the microwave plasma treatment apparatus of the present invention. For suppressing the propagation loss of a microwave as much as possible, Al, Cu, stainless steel (SUS) plated by Ag/Cu, and the like, which have high conductivities, are optimum. Any directions from which a microwave can be efficiently introduced into the microwave propagation space in the endless ring-shaped waveguide with slots 108 may be the direction of the introducing port of the endless ring-shaped waveguide with slots 108 to be used for the present invention, even if the direction is parallel to the H-surface and is a tangential direction of the propagation space, or even if the direction is perpendicular to the H-surface and is one distributing the microwave into two directions of the right direction and the left direction of the propagating space at an introducing part.

Magnetic field generation means may be used for lower pressure treatment in the microwave plasma treatment apparatus and the microwave plasma treatment method of the present invention. Any magnetic fields perpendicular to an electric field to be generated in the width direction of a slot can be applied as the magnetic field to be used for the plasma treatment apparatus and the plasma treatment method of the present invention. A permanent magnet besides a coil may be used as the magnetic field generation means. When a coil is used, cooling means such as a water cooling mechanism and an air cooling mechanism may be used for preventing over heating.

Moreover, for improving the quality of the treatment, ultraviolet light may irradiate the surface of the substrate. Any light sources radiating light to be absorbed by the substrate to be treated or a gas attached on the substrate can be applied as the light source. An excimer laser, an excimer lamp, a rear gas resonance line lamp, a low pressure mercury lamp and the like are suitable.

The pressure in the plasma treatment chamber in the microwave plasma treatment method of the present invention is suitably within a range of from 0.1 mTorr to 10 Torr, more preferably within a range of from 10 mTorr to 5 Torr.

As the formation of the deposited film by the microwave plasma treatment method of the present invention, there can be efficiently formed various deposited films including insulation films such as films made of Si₃N₄, SiO₂, SiOF, Ta₂O₅, TiO₂, TiN, Al₂O₃, AlN and MgF₂, semiconductor films such as films made of a-Si, poly-Is, SiC and GaAs, metal films such as films made of Al, W, Mo, Ti and Ta, and the like.

The substrate to be treated 102, which is treated by the plasma treatment method of the present invention, may be any one of a semiconductor one, a conductive one and an electrically insulating one.

As the conductive substrate, ones made of metals such as Fe, Ni, Cr, Al, Mo, Au, Nb, Ta, V, Ti, Pt and Pb, and their alloys such as brass and stainless steel can be cited.

As the insulating substrate, films or sheets made of various kinds of glass such as quartz glass of a SiO₂ series, inorganic matters such as Si₃N₄, NaCl, KCl, LiF, CaF₂, BaF₂, Al₂O₃, AlN, MgO, and organic matters such as polyethylene, polyester, polycarbonate, cellulose acetate, polypropylene, polyvinyl chloride, polyvinylidene chloride, polystyrene, polyamide and polyimide can be cited.

The direction of the gas introducing means 105 to be used for the plasma treatment apparatus of the present invention is optimally configured to blow a gas toward the dielectric window 108 in order that the gas may flow on the surface of the substrate from the center to the periphery after the gas has been fully supplied into the vicinity of the center after the gas has passed through the plasma area generated in the vicinity of the dielectric window 108.

As the gas to be used in case of forming a thin film on the substrate by the CVD method, a generally known gas can be used.

As the source gas containing Si atoms which gas is introduced into the plasma treatment chamber 101 through the treatment gas introducing means 105 in case of forming the Si series semiconductor thin film made of such as a-Si, poly-Si and SiC, inorganic silane gases such as a SiH₄ gas and a Si₂H₆ gas, organic silane gases such as a tetraethyl silane (TES) gas, a tetramethyl silane (TMS) gas, a dimethyl silane (DMS) gas, a dimethyl difluoro silane (DMDFS) gas and a dimethyl dichlor silane (DMDCS) gas, silane halide gases such as a SiF₄ gas, a Si₂F₆ gas, a Si₃F₈ gas, a SiHF₃ gas, a SiH₂F₂ gas, a SiCl₄ gas, a Si₂Cl₆ gas, a SiHCl₃ gas, a SiH₂Cl₂ gas, a SiH₃Cl gas and a SiCl₂F₂ gas, and the like, all gasses being in a gas state or being able to be easily made to be a gas at an ordinary temperature and under an ordinary pressure, can be cited. Moreover, as an addition gas or a carrier gas which may be mixed with the Si source gas to be introduced in the plasma treatment chamber 101, a H₂ gas, a He gas, a Ne gas, an Ar gas, a Kr gas, an Xe gas and a Rn gas can be cited.

As the raw material containing Si atoms which material is introduced through the treatment gas introducing means 105 in case of forming the Si compound series thin film such as the films made of Si₃N₄ and SiO₂, inorganic silane matters such as SiH₄ and Si₂H₆, organic silane matters such as tetraethoxy silane (TEOS), tetramethoxy silane (TMOS), octamethyl cyclotetra silane (OMCTS), dimethyl difluoro silane (DMDFS) and dimethyl dichlor silane (DMDCS), silane halide such as SiF₄, Si₂F₆, Si₃F₈, SiHF₃, SiH₂F₂, SiCl₄, Si₂Cl₆, SiHCl₃, SiH₂Cl₂, SiH₃Cl and SiCl₂F₂, and the like, all being in a gas state or being able to be easily made to be a gas at an ordinary temperature and under an ordinary pressure, can be cited. Moreover, as a nitrogen source gas or an oxygen source gas which are simultaneously introduced in this case, a N₂ gas, a NH₃ gas, a N₂H₄ gas, a hexamethyl disilazane (HMDS) gas, an O₂ gas, an O₃ gas, a H₂O gas, a NO gas, a N₂O gas, a NO₂ gas and the like can be cited.

As the raw material containing metal atoms which material is introduced through the treatment gas introducing means 105 in case of forming a metal thin film made of Al, W, Mo, Ti, Ta or the like, organic metals such as trimethyl aluminum (TMAl), triethyl aluminum (TEAl), triisobutyl aluminum (TIBAl), dimethyl aluminum hydride (DMAlH), tungsten carbonyl (W(CO)₆), molybdenum carbonyl (Mo(CO)₆), trimethyl gallium (TMGa), triethyl gallium (TEGa), tetraisopropoxy titanium (TIPOTi) and pentaethoxy tantalum (PEOTa), metal halide such as AlCl₃, WF₆, TiCl₃ and TaCl₅, and the like can be cited. Moreover, as an addition gas or a carrier gas which may be mixed with the Si source gas to be introduced in this case, a H₂ gas, a He gas, a Ne gas, an Ar gas, a Kr gas, an Xe gas and a Rn gas can be cited.

As the raw material containing metal atoms which material is introduced through treatment gas introducing means 105 in case of forming a metal compound thin film made of Al₂O₃, AlN, Ta₂O₅, TiO₂, TiN, WO₃ or the like, organic metals such as trimethyl aluminum (TMAl), triethyl aluminum (TEAl), triisobutyl aluminum (TIBAl), dimethyl aluminum hydride (DMAlH), tungsten carbonyl (W(CO)₆), molybdenum carbonyl (Mo(CO)₆), trimethyl gallium (TMGa), triethyl gallium (TEGa), tetraisopropoxy titanium (TIPOTi) and pentaethoxy tantalum (PEOTa), metal halide such as AlCl₃, WF₆, TiCl₃ and TaCl₅, and the like can be cited. Moreover, as an oxygen source gas or a nitrogen source gas which are simultaneously introduced in this case, an O₂ gas, an O₃ gas, a H₂O gas, a NO gas, a N₂O gas, a NO₂ gas, a N₂ gas, an NH₃ gas, a N₂H₄ gas, a hexamethyl disilazane (HMDS) gas and the like can be cited.

As an etching gas to be introduced through the treatment gas introducing port 105 in case of etching the surface of the substrate, a F₂ gas, a CF₄ gas, a CH₂F₂ gas, a C₂F₆ gas, a C₃F₈ gas, a C₄F₈ gas, a CF₂Cl₂ gas, a SF₆ gas, a NF₃ gas, a Cl₂ gas, a CCl₄ gas, a CH₂Cl₂ gas, a C₂Cl₆ gas and the like can be cited.

As an ashing gas to be introduced through the treatment gas introducing port 105 in case of performing the ashing removal of organic components such as photoresist on the surface of the substrate, an O₂ gas, an O₃ gas, a H₂O gas, a NO gas, a N₂O gas, a NO₂ gas, a H₂ gas and the like can be cited.

Moreover, in the case where the micro wave plasma treatment apparatus and the treatment method are also applied to surface modification, by suitably selecting the gas to be used, and by using, for example, Si, Al, Ti, Zn, Ta or the like as the substrate material or the surface layer material, it is possible to perform the oxidization treatment or the nitriding treatment of the substrate or the surface layer, and further the doping treatment of the substrate of the surface layer by the use of B, As, P or the like. Furthermore, the film formation technique adopted by the present invention can be applied also to a cleaning method. In that case, the present invention also can be used for the cleaning of oxides, organic matters and heavy metals.

As the oxidization gas to be introduced through the treatment gas introducing port 105 in the case where the oxidization surface treatment of the substrate is performed, an O₂ gas, an O₃ gas, a H₂O gas, a NO gas, a N₂O gas, a NO₂ gas and the like can be cited. Moreover, as the nitriding gas to be introduced through the treatment gas introducing port 105 in case of the nitriding surface treatment of the substrate, a N₂ gas, an NH₃ gas, a N₂H₄ gas, a hexamethyl disilazane (HMDS) gas and the like can be cited.

As a cleaning or an ashing gas to be introduced through the gas introducing port 105 in case of the cleaning of the organic materials on the surface of the substrate or in case of the ashing removal of the organic components such as photoresist on the surface of the substrate, an O₂ gas, an O₃ gas, a H₂O gas, a NO gas, a N₂O gas, a H₂ gas and the like can be cited. Moreover, as a cleaning gas to be introduced through the plasma generation gas introducing port 105 in case of the cleaning of inorganic matters on the surface of the substrate, a F₂ gas, a CF₄ gas, a CH₂F₂ gas, a C₂F₆ gas, a C₄F₈ gas, a CF₂Cl₂ gas, a SF₆ gas, a NF₃ gas and the like can be cited.

### EXAMPLE

In the following, examples will be cited for describing the microwave plasma treatment apparatus and the treatment method of the present invention more concretely, but the present invention is not limited to those examples.

### Example 1

The microwave plasma treatment apparatus shown in FIGS. 1A and 1B was used for performing the ashing of photoresist.

As the substrate 102, a silicon (Si) substrate (φ: 300 mm) immediately after the formation of via holes after the etching of an interlayer SiO₂ film was used. First, after the setting of the Si substrate 102 on the substrate supporting body 103, the substrate 102 was heated up to the temperature of 250° C. with the heater 104. The inside of the plasma treatment chamber 101 was evacuated through the exhaust system (not shown) to decrease the pressure of the inside up to 10⁻⁴ Torr. An oxygen gas was introduced into the plasma treatment chamber 101 through the plasma treatment gas introducing port 105 at the flow rate of 2 slm. Then, the conductance valve (not shown) provided in the exhaust system (not shown) was adjusted to keep the inside of the treatment chamber 101 at the pressure of 1.5 Torr. Electric power of 2.5 kW was supplied into the plasma treatment chamber 101 from the microwave power source of 2.45 GHz through the endless ring-shaped waveguide 108 with slots 108. Thus, plasma was generated in the plasma treatment chamber 101. At this time, the oxygen gas introduced through the plasma treatment gas introducing port 105 was excited, resolved and reacted to be oxygen atoms in the plasma treatment chamber 101. The oxygen atoms were transported toward the silicon substrate 102 to oxidize the photoresist on the substrate 102, and then the oxygen atoms were vaporized and eliminated. After ashing, the evaluations of a gate dielectric breakdown, an ashing speed and the charge density of the surface of the substrate were performed.

The uniformity of the obtained ashing speed was ±3.4% (6.2 μm/min), which was very good, and the charge density of the surface was 0.5×10¹¹ cm⁻², which was a sufficiently low value. Also no gate dielectric breakdowns could be observed.

### Example 2

The microwave plasma treatment apparatus shown in FIGS. 1A and 1B was used to perform the ashing of photoresist.

As the substrate 102, a silicon (Si) substrate (φ: 12 inches) immediately after the formation of via holes after the etching of an interlayer SiO₂ film was used. First, after the setting of the Si substrate 102 on the substrate supporting body 103, the substrate 102 was heated up to the temperature of 250° C. with the heater 104. The inside of the plasma treatment chamber 101 was evacuated through the exhaust system (not shown) to decrease the pressure of the inside up to 10⁻⁵ Torr. An oxygen gas was introduced into the plasma treatment chamber 101 through the plasma treatment gas introducing port 105 at the flow rate of 2 slm. Then, the conductance valve (not shown) provided in the exhaust system (not shown) was adjusted to keep the inside of the treatment chamber 101 at the pressure of 2 Torr. Electric power of 2.5 kW was supplied into the plasma treatment chamber 101 from the microwave power source of 2.45 GHz through the endless ring-shaped waveguide 108 with slots 108. Thus, plasma was generated in the plasma treatment chamber 101. At this time, the oxygen gas introduced through the plasma treatment gas introducing port 105 was excited, resolved and reacted to be oxygen atoms in the plasma treatment chamber 101. The oxygen atoms were transported toward the silicon substrate 102 to oxidize the photoresist on the substrate 102, and then the oxygen atoms were vaporized and eliminated. After ashing, the evaluations of gate insulation, an ashing speed and the charge density of the surface of the substrate were performed.

The uniformity of the obtained ashing speed was ±4.4% (8.2 μm/min), which was very large, and the charge density of the surface was 1.1×10¹¹ cm⁻², which was a sufficiently low value. Also no gate dielectric breakdowns could be observed.

### Example 3

The microwave plasma treatment apparatus shown in FIGS. 1A and 1B was used for performing the nitriding of the surface of an extremely thin oxide film.

As the substrate 102, a silicon (Si) substrate (φ: 8 inches) having the surface oxidization film of 16 Å in thickness was used. First, after the setting of the Si substrate 102 on the substrate supporting body 103, the substrate 102 was heated up to the temperature of 150° C. with the heater 104. The inside of the plasma treatment chamber 101 was evacuated through the exhaust system (not shown) to decrease the pressure of the inside up to 10⁻³ Torr. A nitrogen gas and a helium gas were introduced into the plasma treatment chamber 101 through the plasma treatment gas introducing port 105 at the flow rates of 500 sccm and 450 sccm, respectively. Then, the conductance valve (not shown) provided in the exhaust system (not shown) was adjusted to keep the inside of the treatment chamber 101 at the pressure of 0.2 Torr. Electric power of 1.5 kW was supplied into the plasma treatment chamber 101 from the microwave power source of 2.45 GHz through the endless ring-shaped waveguide 108 with slots 108. Thus, plasma was generated in the plasma treatment chamber 101. At this time, the nitrogen gas introduced through the plasma treatment gas introducing port 105 was excited, resolved and reacted to be nitrogen ions and atoms in the plasma treatment chamber 101. The nitrogen ions and atoms were transported toward the silicon substrate 102 to nitride the surface of the oxidization film on the substrate 102. After the nitriding, the evaluations of gate insulation, a nitriding speed and the charge density of the surface of the substrate were performed.

The uniformity of the obtained nitriding speed was ±2.2% (6.2 Å/min), which was very good, and the charge density of the surface was 0.9×10¹¹ cm⁻², which was a sufficiently low value. Also no gate dielectric breakdowns could be observed.

### Example 4

The microwave plasma treatment apparatus shown in FIGS. 1A and 1B was used for performing the direct nitriding of the silicon substrate.

As the substrate 102, a bare silicon (Si) substrate (φ: 8 inches) was used. First, after the setting of the Si substrate 102 on the substrate supporting body 103, the substrate 102 was heated up to the temperature of 150° C. with the heater 104. The inside of the plasma treatment chamber 101 was evacuated through the exhaust system (not shown) to decrease the pressure of the inside up to 10⁻³ Torr. A nitrogen gas was introduced into the plasma treatment chamber 101 through the plasma treatment gas introducing port 105 at the flow rate of 500 sccm. Then, the conductance valve (not shown) provided in the exhaust system (not shown) was adjusted to keep the inside of the treatment chamber 101 at the pressure of 0.1 Torr. Electric power of 1.5 kW was supplied into the plasma treatment chamber 101 from the microwave power source of 2.45 GHz through the endless ring-shaped waveguide 108 with slots 108. Thus, plasma was generated in the plasma treatment chamber 101. At this time, the nitrogen gas introduced through the plasma treatment gas introducing port 105 was excited, resolved and reacted to be nitrogen ions and atoms in the plasma treatment chamber 101. The nitrogen ions and atoms were transported toward the silicon substrate 102 to nitride the surface of the silicon substrate 102 directly. After the nitriding, the evaluations of gate insulation, a nitriding speed and the charge density of the surface of the substrate were performed.

The uniformity of the obtained nitriding speed was ±1.6% (22 Å/min), which was very good, and the charge density of the surface was 1.7×10¹¹ cm⁻², which was a sufficiently low value. Also no gate dielectric breakdowns could be observed.

### Example 5

The microwave plasma treatment apparatus shown in FIGS. 1A and 1B was used for forming a silicon nitride film for protecting a semiconductor device.

As the substrate 102, a P type single crystal silicon (Si) substrate (φ: 300 mm) (plane direction: (100); resistivity: 100 Ωcm) with an interlayer SiO₂ film having an Al wiring pattern (line and space: 0.5 μm) was used. First, after the setting of the Si substrate 102 on the substrate supporting body 103, the inside of the plasma treatment chamber 101 was evacuated through the exhaust system (not shown) to decrease the pressure of the inside up to 10⁻⁷ Torr. Successively, the heater 104 was conducted for heating the silicon substrate 102 up to 300° C. to keep the substrate 102 at this temperature. A nitrogen gas and a monosilane gas were introduced into the plasma treatment chamber 101 through the plasma treatment gas introducing port 105 at the flow rates of 600 sccm and 200 sccm, respectively. Next, the conductance valve (not shown) provided in the exhaust system (not shown) was adjusted to keep the inside of the treatment chamber 101 at the pressure of 20 mTorr. Successively, electric power of 3.0 kW was supplied into the plasma treatment chamber 101 from the microwave power source of 2.45 GHz (not shown) through the endless ring-shaped waveguide with slots 108. Thus, plasma was generated in the plasma treatment chamber 101. At this time, the nitrogen gas introduced through the plasma treatment gas introducing port 105 was excited and resolved to be nitrogen atoms in the plasma treatment chamber 101. The nitrogen atoms were transported toward the silicon substrate 102 to react with the monosilane gas. As a result, a silicon nitride film was formed on the substrate 102 in the thickness of 1.0 μm. After the film formation, film qualities such as a gate insulation breakdown, a film formation speed and a stress were evaluated. The stress was obtained by measuring a change of camber quantities of the substrate before and after the film formation with a laser interferometer Zygo (a commercial name).

The uniformity of the film formation speed of the obtained silicon nitride film was ±2.8% (530 nm/min), which was very large, and the film was confirmed to be an extremely good quality film also with respect to the film qualities as follows. That is, the stress was 0.9×10⁹ dyne·cm⁻² (compression); a leakage current was 1.1×10⁻¹⁰ A·cm⁻²; a dielectric voltage was 10.7 MV/cm. Also no gate dielectric breakdowns could be observed.

### Example 6

The microwave plasma treatment apparatus shown in FIGS. 1A and 1B was used for performing the formation of a silicon oxide film and a silicon nitride film for the prevention of the reflection of a plastic lens.

As the substrate 102, a plastic convex lens having a diameter of 50 mm was used. After the lens 102 had been set on the supporting pedestal 103, the inside of the plasma treatment chamber 101 was evacuated through the exhaust system (not shown) to decrease the pressure of the inside up to 10⁻⁷ Torr. A nitrogen gas and a monosilane gas were introduced into the plasma treatment chamber 101 through the plasma treatment gas introducing port 105 at the flow rates of 150 sccm and 70 sccm, respectively. Then, the conductance valve (not shown) provided in the exhaust system (not shown) was adjusted to keep the inside of the treatment chamber 101 at the pressure of 5 mTorr. Electric power of 3.0 kW was supplied into the plasma treatment chamber 101 from the microwave power source of 2.45 GHz (not shown) through the endless ring-shaped waveguide 108 with slots 108. Thus, plasma was generated in the plasma treatment chamber 101. At this time, the nitrogen gas introduced through the plasma treatment gas introducing port 105 was excited and resolved to be activated species of nitrogen atoms and the like in the plasma treatment chamber 101. The activated species were transported toward the lens 102 to react with the monosilane gas. As a result, a silicon nitride film was formed on the lens 102 in the thickness of 20 nm.

Next, the oxygen gas and the monosilane gas were introduced into the plasma treatment chamber 101 through the plasma treatment gas introducing port 105 at the flow rates of 200 sccm and 100 sccm, respectively. Then, the conductance valve (not shown) provided in the exhaust system (not shown) was adjusted to keep the inside of the treatment chamber 101 at the pressure of 2 mTorr. Electric power of 2.0 kW was supplied into the plasma generation chamber 101 from the microwave power source of 2.45 GHz (not shown) through the endless ring-shaped waveguide 108 with slots 108. Thus, plasma was generated in the plasma treatment chamber 101. At this time, the oxygen gas introduced through the plasma treatment gas introducing port 105 was excited and resolved to be activated species of oxygen atoms and the like in the plasma treatment chamber 101. The activated species were transported toward the lens 102 to react with the monosilane gas. As a result, a silicon oxide film was formed on the lens 102 in the thickness of 85 nm. After the film formation, the gate insulation breakdown, a film formation speed and a reflection characteristic of the film were evaluated.

The pieces of the uniformity of the film formation speeds of the obtained silicon nitride film and the silicon oxide film were ±2.6% (390 nm/min) and ±2.8% (420 nm/min), respectively, which were good. The film qualities of the films were also confirmed to have a good optical characteristic. For example, the reflectance of the films in the vicinity of the wavelength of 500 nm was 0.14%.

### Example 7

The microwave plasma treatment apparatus shown in FIGS. 1A and 1B was used for forming a silicon oxide film for the interlayer insulation of a semiconductor device.

As the substrate 102, a P type single crystal silicon substrate (φ: 300 mm) (plane direction: (100); resistivity: 10 Ωcm) with an Al pattern (line and space: 0.5 μm) formed on the uppermost part of the substrate was used. First, the Si substrate 102 was set on the substrate supporting body 103. The inside of the plasma treatment chamber 101 was evacuated through the exhaust system (not shown) to decrease the pressure of the inside up to 10⁻⁷ Torr. Successively, the heater 104 was conducted for heating the silicon substrate 102 up to 300° C. to keep the substrate 102 at this temperature. An oxygen gas and a monosilane gas were introduced into the treatment chamber 101 through the plasma treatment gas introducing port 105 at the flow rates of 400 sccm and 200 sccm, respectively. Next, the conductance valve (not shown) provided in the exhaust system (not shown) was adjusted to keep the inside of the plasma treatment chamber 101 at the pressure of 20 mTorr. Successively, electric power of 300 W was applied to the substrate supporting body 103 through application means of a high frequency of 2 MHz, and electric power of 2.5 kW was supplied into the plasma treatment chamber 101 from the microwave power source of 2.45 GHz through the endless ring-shaped waveguide with slots 108. Thus, plasma was generated in the plasma treatment chamber 101. The oxygen gas introduced through the plasma treatment gas introducing port 105 was excited and resolved to be active species in the plasma treatment chamber 101. The active species were transported toward the silicon substrate 102 to react with the monosilane gas. As a result, a silicon oxide film was formed on the silicon substrate 102 in the thickness of 0.8 μm. AT this time, ion species were accelerated by the radio frequency (RF) bias to enter into the substrate. The input ion species scrape off the film on the pattern to improve the flatness thereof. After the process, a film formation speed, uniformity, a dielectric voltage and step coatability were evaluated. The step coatability was evaluated by observing voids in the observation of a cross section of the silicon oxide film formed on the Al wiring pattern with a scanning electron microscope (SEM).

The uniformity of the film formation speed of the obtained silicon oxide film was ±2.6% (320 nm/min), which was good, and the film was confirmed to be a good quality film also with respect to the film qualities as follows. That is, the dielectric voltage was 9.8 MV/cm, and the film was void-free. Also no gate dielectric breakdowns could be observed.

### Example 8

The microwave plasma treatment apparatus shown in FIGS. 1A and 1B was used for the etching of an interlayer SiO₂ film of a semiconductor device.

As the substrate 102, a P type single crystal silicon substrate (φ: 300 mm) (plane direction: (100); resistivity: 10 Ωcm) with an interlayer SiO₂ films formed on an Al pattern (line and space: 0.35 μm) to be the thickness of 1 μm was used. First, after the Si substrate 102 had been set on the substrate supporting pedestal 103, the inside of the etching chamber 101 was evacuated through the exhaust system (not shown) to decrease the pressure of the inside up to 10⁻⁷ Torr. A C₄F₈ gas, an Ar gas and O₂ gas were introduced into the plasma treatment chamber 101 through the plasma treatment gas introducing port 105 at the flow rates of 80 sccm, 120 sccm and 40 sccm, respectively. Next, the conductance valve (not shown) provided in the exhaust system (not shown) was adjusted to keep the inside of the plasma treatment chamber 101 at the pressure of 5 mTorr. Successively, electric power of 280 W was applied to the substrate supporting body 103 through the application means of the high frequency of 2 MHz, and electric power of 3.0 kW was supplied into the plasma treatment chamber 101 from the microwave power source of 2.45 GHz through the endless ring-shaped waveguide with slots 108. Thus, plasma was generated in the plasma treatment chamber 101. The C₄F₈ gas introduced through the plasma treatment gas introducing port 105 was excited and resolved to be active species in the plasma treatment chamber 101. The active species were transported toward the silicon substrate 102. By the ions accelerated by self-bias, the interlayer SiO₂ film was etched. The substrate temperature rose only up to the temperature of 30° C. owing to a cooler with an electrostatic chuck 104. After the etching, a gate insulation breakdown, an etching speed, a selection ratio and an etched shape were evaluated. The etched shape was evaluated by observing the cross section of the etched silicon oxide film with a scanning electron microscope (SEM).

The uniformity of the etching speed and the selection ratio to polysilicon were ±2.8% (620 nm/min) and 23, respectively, which were good. It were also confirmed that the etched shape was almost vertical, and that a micro loading effect was also small. Furthermore, no gate dielectric breakdowns could be observed.

### Example 9

The microwave plasma treatment apparatus shown in FIGS. 1A and 1B was used for the etching of an polysilicon film between gate electrodes of a semiconductor device.

As the substrate 102, a P type single crystal silicon substrate (φ: 300 mm) (plane direction: (100); resistivity: 10 Ωcm) with a polysilicon film on the uppermost part of the substrate was used. First, after the Si substrate 102 had been set on the substrate supporting pedestal 103, the inside of the plasma treatment chamber 101 was evacuated through the exhaust system (not shown) to decrease the pressure of the inside up to 10⁻⁷ Torr. A CF₄ gas and an oxygen gas were introduced into the plasma treatment chamber 101 through the plasma treatment gas introducing port 105 at the flow rates of 300 sccm and 20 sccm, respectively. Next, the conductance valve (not shown) provided in the exhaust system (not shown) was adjusted to keep the inside of the plasma treatment chamber 101 at the pressure of 2 mTorr. Successively, high frequency electric power of 300 W from a high frequency power source (not shown) of 2 MHz was applied to the substrate supporting body 103, and further electric power of 2.0 kW was supplied into the plasma treatment chamber 101 from the microwave power source of 2.45 GHz through the endless ring-shaped waveguide with slots 108. Thus, plasma was generated in the plasma treatment chamber 101. The CF₄ gas and the oxygen gas introduced through the plasma treatment gas introducing port 105 were excited and resolved to be active species in the plasma treatment chamber 101. The active species were transported toward the silicon substrate 102. By the ions accelerated by self-bias, the polysilicon film was etched. The substrate temperature rose only up to the temperature of 30° C. owing to the cooler with an electrostatic chuck 104. After the etching, a gate insulation breakdown, an etching speed, a selection ratio and an etched shape were evaluated. The etched shape was evaluated by observing the cross section of the etched polysilicon film with a scanning electron microscope (SEM).

The uniformity of the etching speed and the selection ratio to SiO₂ were ±2.8% (780 nm/min) and 25, respectively, which were good. It were also confirmed that the etched shape was vertical, and that the micro loading effect was also small. Furthermore, no gate dielectric breakdowns could be observed.

1. A surface wave plasma treatment apparatus, comprising:
a plasma treatment chamber including a part where said chamber is formed as a dielectric window capable of transmitting a microwave;
a supporting body of a substrate to be treated, said supporting body set in said plasma treatment chamber;
plasma treatment gas introducing means for introducing a plasma treatment gas into said plasma treatment chamber;
exhaust means for evacuating an inside of said plasma treatment chamber; and
microwave introducing means using a multi-slot antenna arranged on an outside of said dielectric window to be opposed to said supporting means of said substrate to be treated, wherein
slots arranged radially along which surface waves propagate into peripheral directions and slots arranged annularly along which the surface waves propagate into radial directions are combined as slots.

2. A surface wave plasma treatment apparatus according to claim 1, wherein said microwave introducing means is a multi-slot antenna including an endless ring-shaped waveguide having an H surface on which said slots are formed.

3. A surface wave plasma treatment apparatus according to claim 1, wherein each interval of centers of said slots arranged radially is odd times as long as a half wavelength of a surface wave.

4. A surface wave plasma treatment apparatus according to claim 1, wherein a diameter of a circle formed by connecting arcs of said slots arranged annularly with each other is even times as long as a half wavelength of a surface wave.

5. A plasma treatment apparatus according to claim 1, wherein a plasma distribution in a radial direction is adjusted by changing microwave emissivities of both of said slots arranged radially and said slots arranged annularly relatively.

6. A surface wave plasma treatment apparatus according to claim 5, wherein the adjustment of a plasma distribution is performed by changing lengths of said slots arranged radially and central angles of said slots arranged annularly.

7. A surface wave plasma treatment apparatus according to claim 5, wherein the adjustment of a plasma distribution is performed by changing widths of said slots arranged radially and said slots arranged annularly.

8. A surface wave plasma treatment apparatus according to claim 5, wherein the adjustment of a plasma distribution is performed by changing thicknesses of said slots arranged radially and said slots arranged annularly.
